(19) United States
(12) Patent Application Publication
(10) Pub. No.: US 2025/0359125 A1
(43) Pub. Date: Nov. 20, 2025

(54) SEMICONDUCTOR DEVICE, SEMICONDUCTOR DEVICE MANUFACTURING METHOD, AND ELECTRONIC DEVICE

(71) Applicant: Fujitsu Limited, Kawasaki-shi (JP)

(72) Inventor: Atsushi YAMADA, Hiratsuka (JP)

(73) Assignee: Fujitsu Limited, Kawasaki-shi (JP)

(21) Appl. No.: 19/280,773

(22) Filed: Jul. 25, 2025

Related U.S. Application Data
(63) Continuation of application No. PCT/JP2023/045652, filed on Dec. 20, 2023.

(30) Foreign Application Priority Data
Feb. 14, 2023 (JP) 2023-020582

(51) Int. Cl. H10D 30/47; H10D 30/01; H10D 62/824

(52) U.S. Cl. CPC H10D 30/474; H10D 30/015; H10D 62/824

(57) ABSTRACT

A semiconductor device including a HEMT using an N polar plane has a semiconductor laminated structure including a base layer, a barrier layer, and a channel layer. The base layer has a first surface, which is a (000-1) plane, and contains AlN. The barrier layer is formed on the first surface side of the base layer where the first surface is provided, contains AlGaN, and is lattice-relaxed with respect to the base layer. The channel layer is formed on a second surface side of the barrier layer and contains GaN. The barrier layer is not lattice-matched with but is lattice-relaxed with respect to the base layer, and the channel layer is lattice-matched with the barrier layer.

### CROSS-REFERENCE TO RELATED APPLICATIONS

This application is a continuation application of International Application PCT/JP2023/045652 filed on Dec. 20, 2023, which designated the U.S., which is based upon and claims the benefit of priority of the prior Japanese Patent Application No. 2023-020582, filed on Feb. 14, 2023, the entire contents of which are incorporated herein by reference.

### FIELD

The embodiments discussed herein are related to a semiconductor device, a semiconductor device manufacturing method, and an electronic device.

### BACKGROUND

A semiconductor device using a nitride semiconductor is known. For example, a high electron mobility transistor (HEMT) in which gallium nitride (GaN) is used for a channel layer (also referred to as an “electron transit layer”) and aluminum gallium nitride (AlGaN) is used for a barrier layer (also referred to as an “electron supply layer”) is known.

As an example, there is known an inverted HEMT including an electron supply layer of AlGaN having a thickness direction of [000-1] with respect to a substrate surface of GaN or the like, an electron transit layer of GaN formed on the electron supply layer, and a gate electrode, a source electrode, and a drain electrode formed on the electron transit layer. See, for example, Japanese Laid-open Patent Publication No. 2006-269534. There is also known an N-polar plane GaN semiconductor device including a buffer layer, such as aluminum nitride (AlN), arranged on a substrate, a barrier layer, such as AlGaN, arranged on the buffer layer, and a GaN channel layer deposited on the barrier layer. See, for example, International Publication Pamphlet No. WO 2013/019516.

### SUMMARY

In one aspect, there is provided a semiconductor device including: a base layer having a first surface and containing AlN, the first surface being a (000-1) plane; a first barrier layer provided on a first surface side of the base layer where the first surface is provided, the first barrier layer containing AlGaN and being lattice-relaxed with respect to the base layer; and a channel layer provided on a second surface side of the first barrier layer opposite to the base layer, the channel layer containing GaN.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are views for describing a first example of a semiconductor device;

FIGS. 2A and 2B are views for describing a second example of the semiconductor device;

FIG. 3 is a view for describing a phenomenon that may occur in the second example of the semiconductor device;

FIGS. 4A to 4C are views for describing an example of a semiconductor laminated structure in a semiconductor device according to a first embodiment;

FIG. 5 view is a for describing the characteristics of the semiconductor laminated structure in the semiconductor device according to the first embodiment;

FIGS. 6A and 6B are views for describing an example of the semiconductor device according to the first embodiment;

FIG. 7 is a view for describing an example of a semiconductor device according to a second embodiment;

FIGS. 8A and 8B are views for describing an example of a method for manufacturing the semiconductor device according to the second embodiment (part 1);

FIGS. 9A and 9B are views for describing the example of the method for manufacturing the semiconductor device according to the second embodiment (part 2);

FIG. 10 is a view for describing an example of a semiconductor device according to a third embodiment;

FIGS. 11A and 11B are views for describing an example of a method for manufacturing the semiconductor device according to the third embodiment (part 1);

FIGS. 12A and 12B are views for describing the example of the method for manufacturing the semiconductor device according to the third embodiment (part 2);

FIG. 13 is a view for describing an example of a semiconductor device according to a fourth embodiment;

FIG. 14 is a view for describing an example of a semiconductor package according to a fifth embodiment;

FIG. 15 is a view for describing an example of a power factor correction circuit according to a sixth embodiment;

FIG. 16 is a view for describing an example of a power supply device according to a seventh embodiment; and

FIG. 17 is a view for describing an example of an amplifier according to an eighth embodiment.

### DESCRIPTION OF EMBODIMENTS

There is known a semiconductor device including a HEMT in which AlN having a large band offset with respect to GaN is used as an underlayer and in which GaN of a channel layer is formed on the N-polar plane side that is a (000-1) plane of the underlayer. With this semiconductor device, a relatively strong spontaneous polarization of AlN of the underlayer is utilized to generate a two-dimensional electron gas (2DEG) in GaN of the channel layer.

In such a semiconductor device, AlN which differs greatly in lattice constant from GaN is used for the underlayer. It is assumed that GaN of the channel layer is formed on the N-polar surface side of AlN of the underlayer directly or with a barrier layer, such as AlGaN, therebetween. If the lattice constant difference between GaN of the channel layer and the underlayer (underlayer or barrier layer) is large, then GaN of the channel layer is lattice-relaxed. Lattice defects appear at or near the junction interface between GaN of the channel layer lattice-relaxed and the underlayer thereof. These lattice defects cause the 2DEG in GaN of the channel layer to disappear. The disappearance of the 2DEG in GaN of the channel layer may cause an increase in the resistance of the semiconductor device.

A semiconductor device using a nitride semiconductor has been developed as a high breakdown voltage and high output device by utilizing characteristics such as a high saturation electron velocity and a wide band gap. Reports have been given in large numbers on a field effect transistor (FET), for example, a HEMT as a semiconductor device using a nitride semiconductor. As one of HEMTs, a HEMT using AlGaN as a barrier layer and using GaN as a channel layer is known. With such a HEMT, a piezoelectric polarization is generated in AlGaN due to spontaneous polarization of AlGaN and a strain caused by a lattice constant difference between AlGaN and GaN. As a result, 2DEG is generated in GaN. Accordingly, a high power device is realized.

In order to improve the performance of a semiconductor device using a nitride semiconductor, there has been proposed a semiconductor device having an AlN/GaN/AlN quantum confinement structure in which confinement of electrons serving as carriers is enhanced by a large band offset between AlN and GaN to improve electron mobility.

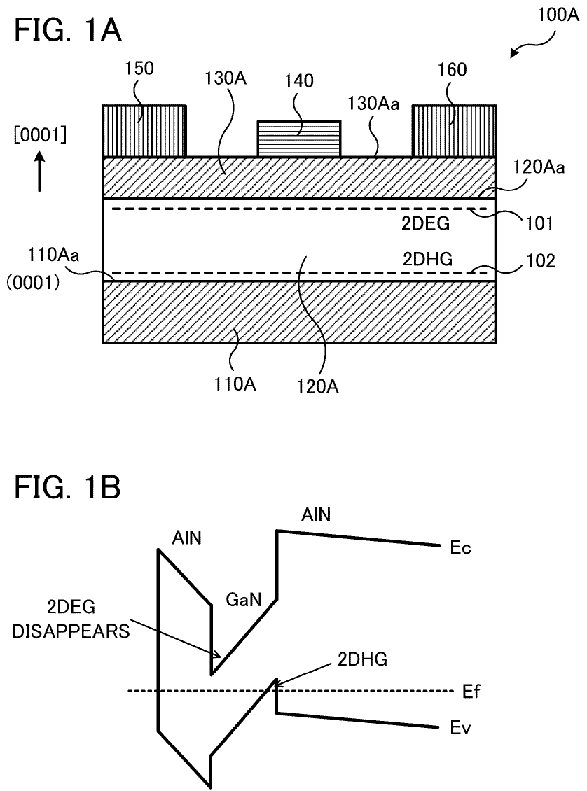

FIGS. 1A and 1B are views for describing a first example of a semiconductor device. FIG. 1A is a fragmentary schematic sectional view of the first example of a semiconductor device. FIG. 1B schematically illustrates an energy band structure of the first example of the semiconductor device. In FIG. 1B, Ec indicates a conduction band, Ev indicates a valence band, and Ef indicates a Fermi level.

A semiconductor device 100A illustrated in FIG. 1A is an example of a HEMT having an AlN/GaN/AlN quantum confinement structure. The semiconductor device 100A includes a barrier layer 110A, a channel layer 120A, a barrier layer 130A, a gate electrode 140, a source electrode 150, and a drain electrode 160. AlN is used for forming the barrier layer 110A and the barrier layer 130A. The channel layer 120A is formed between the barrier layer 110A and the barrier layer 130A. GaN is used for forming the channel layer 120A. The gate electrode 140, the source electrode 150, and the drain electrode 160 are formed, for example, on the barrier layer 130A. Predetermined metals are used for forming the gate electrode 140, the source electrode 150, and the drain electrode 160. The gate electrode 140 is formed so as to function as a Schottky electrode. The source electrode 150 and the drain electrode 160 are formed so as to function as an ohmic electrode.

With the semiconductor device 100A, the barrier layer 110A, the channel layer 120A, and the barrier layer 130A are grown and laminated by, for example, a metal organic chemical vapor deposition (MOCVD) method, a metal organic vapor phase epitaxy; MOVPE) method, or a molecular beam epitaxy (MBE) method. A substrate serving as a growth base of the channel layer 120A laminated thereon (and the barrier layer 130A laminated thereon) may be used for the barrier layer 110A.

The barrier layer 110A is a layer containing AlN whose thickness direction is a direction, and is a layer whose surface 110Aa on which the channel layer 120A is laminated is a (0001) plane, that is to say, a group III (Al) polar plane. The channel layer 120A is a layer containing GaN grown on the surface 110Aa ((0001) plane) of the barrier layer 110A so that the thickness direction thereof is the direction, and is a layer in which a surface 120Aa on which the barrier layer 130A is laminated is the (0001) plane, that is to say, a group III (Ga) polar plane. The barrier layer 130A is a layer containing AlN grown on the surface 120Aa ((0001) plane) of the channel layer 120A so that the thickness direction thereof is the direction, and is a layer in which a surface 130Aa opposite to the channel layer 120A is the (0001) plane, that is to say, a group III (Al) polar plane.

The semiconductor device 100A of the first example has an AlN/GaN/AlN quantum confinement structure using a group III (Al or Ga) polar plane. With the semiconductor device 100A, since AlN of the barrier layer 130A having a lattice constant smaller than that of GaN of the channel layer 120A is formed on GaN of the channel layer 120A, piezoelectric polarization occurs in the barrier layer 130A. A 2DEG 101 is generated in the channel layer 120A near the junction interface between the barrier layer 130A and the channel layer 120A by spontaneous polarization of AlN of the barrier layer 130A and piezoelectric polarization generated in AlN of the barrier layer 130A due to a lattice constant difference between GaN of the channel layer 120A and AlN of the barrier layer 130A. If the Fermi level Ef is higher than the conduction band Ec at the junction interface between GaN of the channel layer 120A and AlN of the barrier layer 130A, then the 2DEG 101 is generated in the channel layer 120A near the junction interface between the channel layer 120A and the barrier layer 130A. When the semiconductor device 100A operates, a predetermined voltage is applied between the source electrode 150 and the drain electrode 160 and a predetermined voltage is applied to the gate electrode 140. An electric field effect produced by the voltage applied to the gate electrode 140 controls the amount of electric charges passing through the channel layer 120A just under the gate electrode 140 between the source electrode 150 and the drain electrode 160. As a result, an output of the semiconductor device 100A is controlled.

With the semiconductor device 100A having the AlN/GaN/AlN quantum confinement structure using the group III (Al or Ga) polar plane, GaN of the channel layer 120A is formed between AlN of the barrier layer 110A and AlN of the barrier layer 130A. As a result, confinement of electrons is enhanced. Therefore, with the semiconductor device 100A, it is expected that diffusion of electrons in the channel layer 120A is suppressed and that the occurrence of a leakage current, a decrease in electron transport efficiency caused by the leakage current, and the like are suppressed.

However, with the semiconductor device 100A having the AlN/GaN/AlN quantum confinement structure using the group III polar plane, relatively strong spontaneous polarization occurs in the barrier layer 110A under the channel layer 120A. Because of the relatively strong spontaneous polarization generated in the barrier layer 110A, as illustrated in FIGS. 1A and 1B, a two-dimensional hole gas (2DHG) 102 is generated in GaN of the channel layer 120A near the junction interface between GaN of the channel layer 120A and AlN of the barrier layer 110A. With the semiconductor device 100A, as illustrated in FIG. 1B, the conduction band Ec and the valence band Ev of the channel layer 120A are raised by the relatively strong spontaneous polarization generated in the barrier layer 110A, and the 2DHG 102 is generated in GaN of the channel layer 120A near the junction interface between GaN of the channel layer 120A and AlN of the barrier layer 110A. With the semiconductor device 100A, the 2DEG 101 generated in GaN of the channel layer 120A near the junction interface on the surface 120Aa side between GaN of the channel layer 120A and AlN of the barrier layer 130A may disappear because of the 2DHG 102. Such disappearance of the 2DEG 101 is more likely to occur as GaN of the channel layer 120A becomes thinner. The disappearance of the 2DEG 101 may cause a decrease in electron concentration in GaN of the channel layer 120A and an increase in resistance by the decrease in the electron concentration.

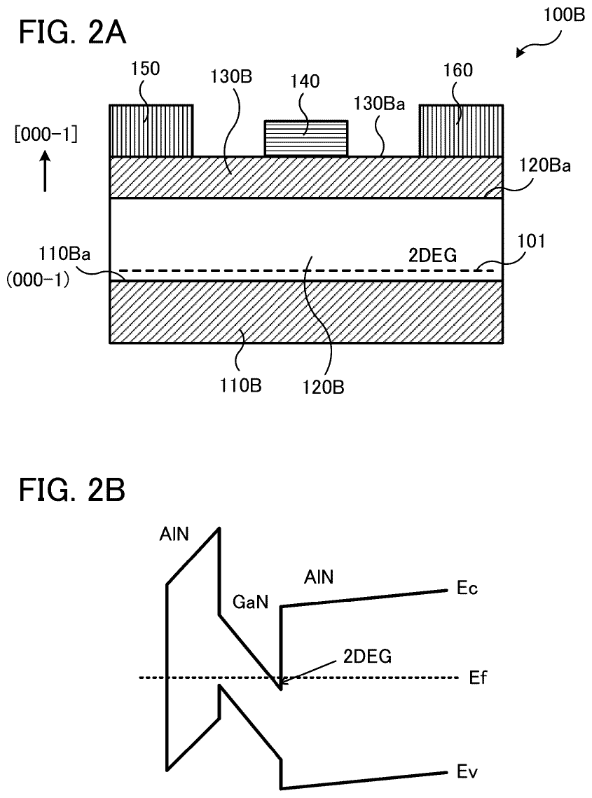

FIGS. 2A and 2B are views for describing a second example of the semiconductor device. FIG. 2A is a fragmentary schematic sectional view of the second example of the semiconductor device. FIG. 2B schematically illustrates an energy band structure of the second example of the semiconductor device. In FIG. 2B, Ec indicates a conduction band, Ev indicates a valence band, and Ef indicates a Fermi level.

A semiconductor device 100B illustrated in FIG. 2A is an example of a HEMT having an AlN/GaN/AlN quantum confinement structure. The semiconductor device 100B includes a barrier layer 110B, a channel layer 120B, a barrier layer 130B, a gate electrode 140, a source electrode 150, and a drain electrode 160. AlN is used for forming the barrier layer 110B and the barrier layer 130B. The channel layer 120B is formed between the barrier layer 110B and the barrier layer 130B. GaN is used for forming the channel layer 120B. The gate electrode 140, the source electrode 150, and the drain electrode 160 are formed, for example, on the barrier layer 130B. Predetermined metals are used for forming the gate electrode 140, the source electrode 150, and the drain electrode 160. The gate electrode 140 is formed so as to function as a Schottky electrode. The source electrode 150 and the drain electrode 160 are formed so as to function as an ohmic electrode.

With the semiconductor device 100B, the barrier layer 110B, the channel layer 120B, and the barrier layer 130B are grown and laminated by the use of the MOVPE method or the like. The barrier layer 110B may be a substrate serving as a growth base of the channel layer 120B (and the barrier layer 130B laminated thereon) laminated thereon.

The barrier layer 110B is a layer containing AlN whose thickness direction is a [000-1] direction, and is a layer whose surface 110Ba on which the channel layer 120B is laminated is a (000-1) plane, that is to say, an N polar plane. The channel layer 120B is a layer containing GaN grown on the surface 110Ba ((000-1) plane) of the barrier layer 110B so that the thickness direction thereof is the [000-1] direction, and is a layer in which a surface 120Ba on which the barrier layer 130B is laminated is the (000-1) plane, that is, the N polar plane. The barrier layer 130B is a layer containing AlN grown on the surface 120Ba ((000-1) plane) of the channel layer 120B so that the thickness direction thereof is the [000-1] direction, and is a layer in which a surface 130Ba opposite to the channel layer 120B is the (000-1) plane, that is to say, the N polar plane.

The semiconductor device 100B of the second example has an AlN/GaN/AlN quantum confinement structure using the N polar plane. With the semiconductor device 100B, a 2DEG 101 is generated in GaN of the channel layer 120B near the junction interface between GaN of the channel layer 120B and AlN of the underlying barrier layer 110B. If the Fermi level Ef is higher than the conduction band Ec at the junction interface between GaN of the channel layer 120B and AlN of the underlying barrier layer 110B, then the 2DEG 101 is generated in the channel layer 120B near the junction interface between the channel layer 120B and the barrier layer 110B. When the semiconductor device 100B operates, a predetermined voltage is applied between the source electrode 150 and the drain electrode 160 and a predetermined voltage is applied to the gate electrode 140. An electric field effect produced by the voltage applied to the gate electrode 140 controls the amount of electric charges passing through the channel layer 120B just under the gate electrode 140 between the source electrode 150 and the drain electrode 160. As a result, an output of the semiconductor device 100B is controlled.

With the semiconductor device 100B having the AlN/GaN/AlN quantum confinement structure using the N polar plane, as illustrated in FIGS. 2A and 2B, it is expected that the 2DEG 101 is generated in GaN of the channel layer 120B on the AlN side of the underlying barrier layer 110B. As illustrated in FIG. 2B, it is expected that generation of the 2DHG 102 (FIGS. 1A and 1B) in GaN of the channel layer 120B on the AlN side of the overlying barrier layer 130B is suppressed. With the semiconductor device 100B in which the 2DEG 101 is generated in GaN of the channel layer 120B on the AlN side of the underlying barrier layer 110B, it is expected that the channel layer 120B is thinned.

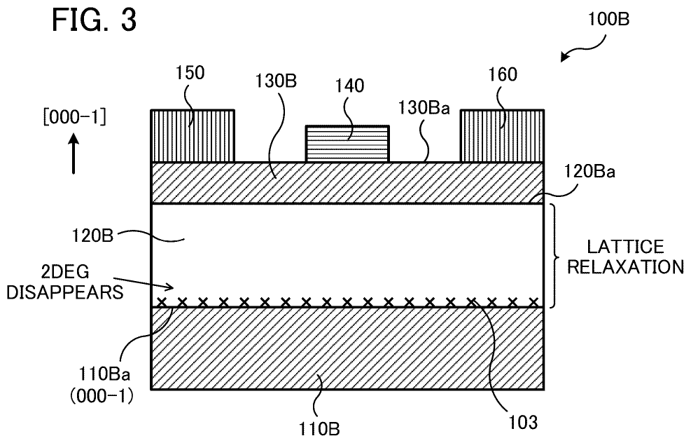

However, with the semiconductor device 100B having the AlN/GaN/AlN quantum confinement structure using the N polar plane, the disappearance of the 2DEG 101 and the resultant increase in resistance may occur due to the lattice constant difference between the channel layer 120B and the underlying barrier layer 110B. This will be described with reference to FIG. 3.

FIG. 3 is a view for describing a phenomenon that may occur in the second example of the semiconductor device. FIG. 3 is a fragmentary schematic sectional view of the second example of the semiconductor device.

With the semiconductor device 100B having the AlN/GaN/AlN quantum confinement structure using the N polar plane, the channel layer 120B is grown on the surface 110Ba, which is the N polar plane ((000-1) plane), of the underlying barrier layer 110B. AlN is used for forming the barrier layer 110B and GaN is used for the channel layer 120B. In this case, there is a relatively large lattice constant difference between AlN and GaN. Therefore, GaN of the channel layer 120B grows on AlN of the barrier layer 110B while introducing dislocations. As a result, lattice relaxation occurs.

As illustrated in FIG. 3, a relatively large number or a high density of lattice defects 103 appear at the junction interface between the barrier layer 110B of AN and the channel layer 120B of lattice-relaxed GaN or in a growth initial layer of the channel layer 120B near the junction interface. When the lattice defects 103 appear, the 2DEG 101 (FIGS. 2A and 2B) generated in the channel layer 120B of GaN near the junction interface between the channel layer 120B of GaN and the barrier layer 110B of AlN disappears. With the semiconductor device 100B, the disappearance of the 2DEG 101 caused by the lattice defects 103 may increase the resistance of the channel layer 120B and the resistance of the semiconductor device 100B including the channel layer 120B.

The semiconductor device 100B having the AlN/GaN/AlN quantum confinement structure using the N polar plane has been taken as an example. The appearance of the above lattice defects 103 between the barrier layer 110B and the channel layer 120B, the disappearance of the 2DEG 101 caused by the lattice defects 103, and an increase in the resistance of the channel layer 120B due to the disappearance of the 2DEG 101 may occur in the same way with a semiconductor device not including the overlying barrier layer 130B. That is to say, with a semiconductor device including at least the underlying barrier layer 110B and the channel layer 120B and using an N polar plane, the appearance of the above lattice defects 103, the disappearance of the 2DEG 101 caused by the lattice defects 103, and an increase in the resistance of the channel layer 120B caused by the disappearance of the 2DEG 101 may occur in the same way.

In view of the above points, a high performance semiconductor device in which an increase in resistance caused by the disappearance of a 2DEG is suppressed is realized by adopting structures described below as embodiments.

### First Embodiment

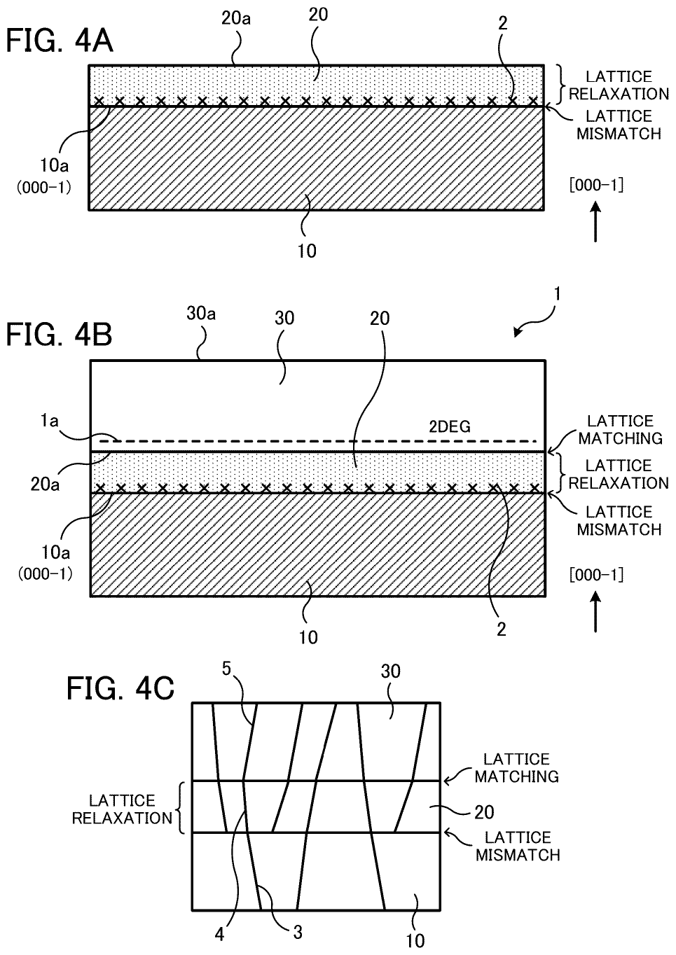

FIGS. 4A to 4C are views for describing an example of a semiconductor laminated structure in a semiconductor device according to a first embodiment. Each of FIGS. 4A to 4C is a fragmentary schematic sectional view of an example of a semiconductor laminated structure.

FIGS. 4A and 4B schematically illustrate a process (FIGS. 4A and 4B) for forming a semiconductor laminated structure 1 used in a semiconductor device including a HEMT and a structure example (FIG. 4B) of the semiconductor laminated structure 1 formed by the process. As illustrated in FIG. 4A, a barrier layer 20 is grown on a surface 10a of a base layer 10 and then, as illustrated in FIG. 4B, a channel layer 30 is grown on a surface 20a of the barrier layer 20. By doing so, the semiconductor laminated structure 1 is formed. AlN is used for forming the base layer 10. AlGaN is used for forming the barrier layer 20. GaN is used for forming the channel layer 30. A nitride semiconductor having a band gap larger than that of a nitride semiconductor used for forming the channel layer 30 is used for forming the base layer 10 and the barrier layer 20. The barrier layer 20 and the channel layer 30 are grown by the MOVPE method or the like. The base layer 10 itself may be a substrate, such as a self-supporting substrate, or may be a layer grown on another substrate (not illustrated) by the MOVPE method or the like. For example, the base layer 10 may be an AlN self-supporting substrate or may be an AlN layer grown on various substrates such as AlN, GaN, silicon (Si), silicon carbide (Sic), sapphire, and diamond.

The base layer 10 is a layer containing AlN whose thickness direction is a [000-1] direction, and is a layer whose surface 10a on which the barrier layer 20 is laminated is a (000-1) plane, that is to say, an N polar plane. The barrier layer 20 is a layer containing AlGaN grown on the surface 10a ((000-1) plane) of the base layer 10 so that the thickness direction thereof is the [000-1] direction, and is a layer in which the surface 20a on which the channel layer 30 is laminated is the (000-1) plane, that is to say, the N polar plane. The channel layer 30 is a layer containing GaN grown on the surface 20a ((000-1) plane) of the barrier layer 20 so that the thickness direction thereof is the [000-1] direction, and is a layer in which a surface 30a opposite to the barrier layer 20 side is the (000-1) plane, that is to say, the N polar plane.

The surface 10a of the base layer 10 is also referred to as a “first surface”. The barrier layer 20 formed on the surface 10a of the base layer 10 is also referred to as a “first barrier layer”. The surface 20a of the barrier layer 20 opposite to the base layer 10 is also referred to as a “second surface”. The surface 30a of the channel layer opposite to the barrier layer 20 is also referred to as a “third surface”.

In the formation of the semiconductor laminated structure 1, first, as illustrated in FIG. 4A, the barrier layer 20 of AlGaN is grown on the surface 10a, which is the N polar surface, of the base layer 10 of AlN. AlGaN which differs relatively much from AlN of the base layer 10 in lattice constant is grown as the barrier layer 20. For example, AlGaN having a relatively low aluminum (Al) composition of less than 0.3, that is to say, AlGaN having an Al composition x<0.3 when expressed by the general formula AlₓGa₁₋ₓN is grown as the barrier layer 20. If AlGaN which differs relatively much from AlN in lattice constant is grown as the barrier layer 20 on the surface 10a of the base layer 10 of AlN, then AlGaN of the barrier layer 20 is not lattice-matched with AlN of the base layer 10 (lattice mismatch). As a result, AlGaN grows while introducing dislocations, and is lattice-relaxed. Therefore, as illustrated in FIG. 4A, a relatively large number or a high density of lattice defects 2 appear at the junction interface between the base layer 10 of AlN and the barrier layer 20 of lattice-relaxed AlGaN or in a growth initial layer of the barrier layer 20 near the junction interface.

After the growth of the barrier layer 20, as illustrated in FIG. 4B, the channel layer 30 of GaN is grown on the surface 20a, which is the N polar surface, of the barrier layer 20 of AlGaN. GaN of the channel layer 30 differs relatively slightly in lattice constant from AlGaN of the barrier layer 20 having a relatively low Al composition (having a composition relatively close to GaN), which is grown on AlN of the base layer 10 and is lattice-relaxed. Therefore, GaN of the channel layer 30 is lattice-matched with AlGaN of the barrier layer 20, and grows on the surface 20a while suppressing introduction of new dislocations. This suppresses the appearance of lattice defects at the junction interface between the barrier layer of AlGaN and the channel layer 30 of GaN lattice-matched therewith, or in a growth initial layer of the channel layer near the junction interface. In the channel layer 30 in which the appearance of lattice defects is suppressed, a high-concentration 2DEG 1a is generated near the junction interface between the barrier layer 20 and the channel layer by polarization (spontaneous polarization and piezoelectric polarization) of the base layer 10 and the barrier layer 20.

For example, if the channel layer 30 of GaN is grown directly on the base layer 10 of AN, then the same phenomenon that occurs in the case illustrated in FIG. 3 where the channel layer 120B of GaN is grown directly on the barrier layer 110B of AlN may occur. That is to say, dislocations are introduced into the channel layer 30 due to a relatively large lattice constant difference between GaN of the channel layer 30 and AlN of the base layer 10, lattice defects appear at the junction interface between the base layer 10 and the channel layer 30 or near the junction interface, and the disappearance of 2DEG in the channel layer 30 and an increase in resistance may occur.

In contrast, with the semiconductor laminated structure 1, the barrier layer 20 of AlGaN that is lattice-relaxed with respect to the base layer 10 of AlN is formed between the base layer 10 of AlN and the channel layer 30 of GaN. The barrier layer 20 of AlGaN, which is lattice-relaxed with respect to the base layer 10 of AlN, is not lattice-matched with the base layer 10 of AlN, which differs relatively much in lattice constant from AlGaN, and lattice defects 2 appear at the junction interface between the barrier layer 20 and the base layer 10 or in the barrier layer 20 near the junction interface. The channel layer 30 of GaN is grown on the barrier layer 20 of lattice-relaxed AlGaN so as to be lattice-matched with the barrier layer 20, and the appearance of lattice defects at the junction interface between the barrier layer 20 and the channel layer or in the channel layer 30 near the junction interface is suppressed. In the channel layer 30 in which the appearance of lattice defects is suppressed, a high-concentration 2DEG 1a is generated near the junction interface between the barrier layer 20 and the channel layer by polarization of the base layer 10 and the barrier layer 20. With the semiconductor laminated structure 1, because the appearance of lattice defects in the channel layer 30 is suppressed, the disappearance of a 2DEG 1a in the channel layer 30 caused by lattice defects is suppressed, and an increase in the resistance of the channel layer 30 caused by the disappearance of the 2DEG 1a is effectively suppressed.

In the semiconductor laminated structure 1, the thickness of AlN of the base layer 10 in the [000-1] direction is preferably 200 nm or more from the viewpoint of obtaining spontaneous polarization and piezoelectric polarization for generating sufficient 2DEG 1a in the channel layer 30.

Furthermore, FIG. 4C illustrates the relationship between dislocation densities in the base layer 10, the barrier layer 20, and the channel layer 30. The base layer may include dislocations 3 at a certain density before the growth of the barrier layer 20. The barrier layer 20 grown on the base layer 10 includes dislocations 4 reflecting the dislocations 3 of the base layer 10 and dislocations 4 introduced by lattice mismatch with the base layer 10. The barrier layer 20 is lattice-relaxed by the introduction of the dislocations 4, and the lattice defects 2 appear at the junction interface between the barrier layer 20 and the base layer 10 or in the barrier layer 20 near the junction interface as illustrated in FIGS. 4A and 4B. The density of the dislocations 4 (dislocation density) in the barrier layer 20 is higher than the density of the dislocations 3 (dislocation density) in the base layer 10. The channel layer 30 grown on the barrier layer 20 includes dislocations reflecting the dislocations 4 in the barrier layer 20. Because the channel layer 30 is lattice-matched with the barrier layer 20, the introduction of new dislocations is suppressed and the appearance of lattice defects is suppressed. The density of the dislocations 5 (dislocation density) in the channel layer 30 is equal to the density of the dislocations 4 in the barrier layer 20 and is higher than the density of the dislocations 3 in the base layer 10.

The characteristics of the above semiconductor laminated structure 1 will now be described.

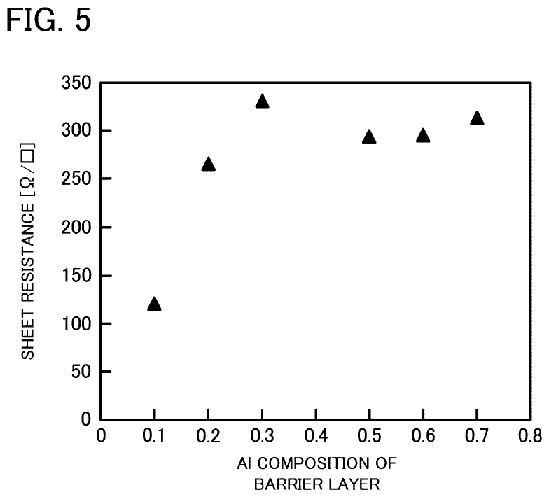

FIG. 5 is a view for describing the characteristics of the semiconductor laminated structure in the semiconductor device according to the first embodiment. FIG. 5 illustrates an example of the relationship between the Al composition of the barrier layer and the sheet resistance [Ω/□] of the semiconductor laminated structure.

AlGaN expressed by the general formula AlₓGa₁₋ₓN is used for forming the barrier layer 20 of the semiconductor laminated structure 1. FIG. 5 illustrates the sheet resistance of the semiconductor laminated structure 1 obtained when the Al composition x of AlₓGa₁₋ₓN of the barrier layer 20 is changed. From FIG. 5, it is recognized that the sheet resistance tends to decrease when the Al composition of AlGaN of the barrier layer 20 is less than 0.3. This is considered as follows.

When the Al composition of AlGaN of the barrier layer 20 becomes relatively low, the lattice constant difference between AlN and AlGaN becomes relatively large. Therefore, the AlN base layer 10 and the AlGaN barrier layer grown thereon are not lattice-matched and the AlGaN barrier layer 20 is lattice-relaxed. As a result, the lattice defects 2 appear at the junction interface between the barrier layer 20 of AlGaN and the base layer 10 of AlN or in the barrier layer 20 near the junction interface. On the other hand, the difference in lattice constant between lattice-relaxed AlGaN having a relatively low Al composition and GaN is relatively small. Therefore, the barrier layer of AlGaN and the channel layer 30 of GaN grown thereon are lattice-matched. As a result, the appearance of lattice defects is suppressed at the junction interface between the channel layer 30 of GaN and the barrier layer 20 of AlGaN or in the channel layer 30 near the junction interface. Accordingly, the high-concentration 2DEG 1a is effectively generated in the channel layer 30, and the sheet resistance is reduced.

On the other hand, when the Al composition of AlGaN of the barrier layer 20 becomes relatively high, the lattice constant difference between AlN and AlGaN becomes relatively small. Therefore, the lattice relaxation of the AlGaN barrier layer 20 grown on the AlN base layer 10 is suppressed, and the appearance of lattice defects at the junction interface between the barrier layer 20 of AlGaN and the base layer 10 of AlN or in the barrier layer 20 near the junction interface is suppressed. On the other hand, there is a relatively large lattice constant difference between AlGaN which has a relatively high Al composition and in which lattice relaxation is suppressed and GaN. Therefore, the barrier layer 20 of AlGaN and the channel layer 30 of GaN grown thereon are not lattice-matched, and lattice defects appear at the junction interface between the channel layer 30 of GaN and the barrier layer 20 of AlGaN or in the channel layer 30 near the junction interface. As a result, the 2DEG 1a in the channel layer 30 disappears because of the lattice defects and the sheet resistance increases.

Accordingly, by making the Al composition of AlGaN of the barrier layer 20 relatively low, a high-concentration 2DEG 1a is generated in the channel layer 30 and the sheet resistance is reduced. From the knowledge obtained from FIG. 5, the Al composition of AlGaN of the barrier layer 20 is set to a value smaller than 0.3, that is to say, the Al composition x when expressed by the general formula AlₓGa₁₋ₓN is set to a value in the range of 0<x<0.3. This makes it possible to effectively generate a high-concentration 2DEG 1a in the channel layer 30 and reduce the sheet resistance.

An example of a semiconductor device in which the above semiconductor laminated structure 1 is adopted will now be described.

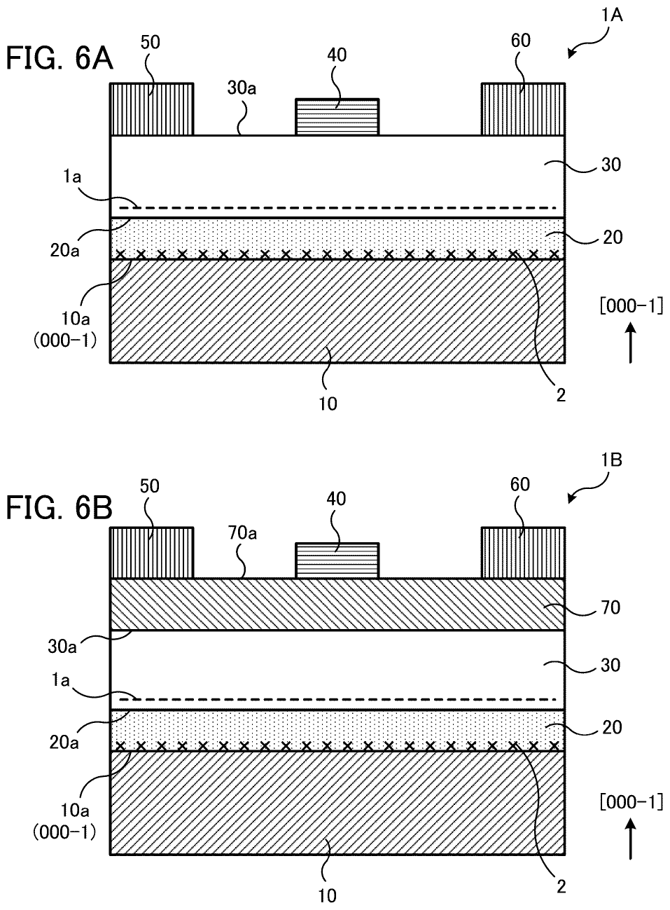

FIGS. 6A and 6B are views for describing an example of a semiconductor device according to a first embodiment. Each of FIGS. 6A and 6B is a fragmentary schematic sectional view of an example of a semiconductor device.

A semiconductor device 1A illustrated in FIG. 6A is an example of a HEMT using the above semiconductor laminated structure 1 utilizing the N polar plane. The semiconductor device 1A includes a channel layer 30 of GaN formed on a base layer 10 of AlN with a barrier layer 20 of lattice-relaxed AlGaN therebetween. The Al composition of AlGaN of the barrier layer 20 is set to a value, for example, less than 0.3. The barrier layer 20 is formed on a surface 10a, which is an N polar plane, of the base layer 10 and the channel layer 30 is formed on a surface 20a, which is an N polar plane, of the barrier layer 20. A 2DEG 1a is generated in the channel layer 30 near the junction interface between the channel layer 30 and the barrier layer 20.

The semiconductor device 1A includes a gate electrode 40, a source electrode 50, and a drain electrode 60 formed on a surface 30a of the channel layer 30. The source electrode 50 and the drain electrode 60 are formed on both sides of the gate electrode 40. The source electrode 50 and the drain electrode 60 are formed on the channel layer 30 so as to be separated from each other. The gate electrode 40 is formed between the source electrode 50 and the drain electrode 60 so as to be separated therefrom. Predetermined metals are used for forming the gate electrode 40, the source electrode 50, and the drain electrode 60. For example, a metal, such as nickel (Ni) or gold (Au), is used for forming the gate electrode 40. For example, a metal, such as tantalum (Ta) or Al, is used for forming the source electrode 50 and the drain electrode 60. The gate electrode is formed so as to function as a Schottky electrode. The source electrode 50 and the drain electrode 60 are formed so as to function as an ohmic electrode.

When the semiconductor device 1A operates, a predetermined voltage is applied between the source electrode 50 and the drain electrode 60 and a predetermined voltage is applied to the gate electrode 40. An electric field effect produced by the voltage applied to the gate electrode 40 controls the amount of electric charges passing through the channel layer 30 right under the gate electrode between the source electrode 50 and the drain electrode 60. As a result, an output of the semiconductor device 1A is controlled.

In the semiconductor device 1A, the barrier layer of AlGaN having an Al composition less than 0.3 does not lattice-match the base layer 10 of AlN. Therefore, the barrier layer 20 of AlGaN grows on the base layer 10 of AlN while lattice-relaxing, and lattice defects 2 appear at the junction interface between the barrier layer 20 of AlGaN and the base layer 10 of AlN or in the barrier layer 20 near the junction interface. On the other hand, the channel layer 30 of GaN is lattice-matched with the barrier layer 20 of lattice-relaxed AlGaN. Therefore, the appearance of lattice defects is suppressed at the junction interface between the barrier layer 20 of AlGaN and the channel layer 30 of GaN grown on the barrier layer 20 of AlGaN or in the channel layer 30 near the junction interface. Therefore, with the semiconductor device 1A, the disappearance of the 2DEG 1a in the channel layer 30 caused by lattice defects is suppressed. As a result, the high-performance semiconductor device 1A in which an increase in resistance caused by the disappearance of the 2DEG 1a is suppressed is realized.

In addition, a semiconductor device 1B illustrated in FIG. 6B has a structure in which a barrier layer 70 is further formed on the surface 30a, which is an N polar plane, of the channel layer 30 and in which the gate electrode 40, the source electrode 50, and the drain electrode 60 are formed on a surface 70a. The semiconductor device 1B differs from the semiconductor device 1A illustrated in FIG. 6A in that the semiconductor device 1B has the above structure.

A nitride semiconductor having a band gap larger than that of a nitride semiconductor used for forming the channel layer 30 is used for forming the barrier layer 70. For example, InAlGaN, AlGaN, InAlN, or AlN is used for forming the barrier layer 70. That is to say, for example, a nitride semiconductor expressed by the general formula In_{y}Al_{z}Ga_{1-y-z}N (0≤y≥0.2 and 0<z≤1) is used for forming the barrier layer 70.

With the semiconductor device 1B, a barrier layer of AlGaN having an Al composition less than 0.3 is not lattice-matched with a base layer 10 of AlN and the channel layer 30 of GaN is lattice-matched with the barrier layer of AlGaN. This is the same with the above semiconductor device 1A. The barrier layer 20 of lattice-relaxed AlGaN that is not lattice-matched with the base layer 10 of AN is formed on the base layer 10, and the channel layer 30 of GaN that is lattice-matched with the barrier layer 20 of lattice-relaxed AlGaN is formed on the barrier layer 20. Therefore, the appearance of lattice defects at the junction interface between the channel layer 30 and the barrier layer or in the channel layer 30 near the junction interface is suppressed. As a result, the disappearance of a 2DEG 1a in the channel layer 30 caused by lattice defects is suppressed. Accordingly, the high-performance semiconductor device 1B in which an increase in resistance caused by the disappearance of the 2DEG 1a is suppressed is realized.

Furthermore, with the semiconductor device 1B, a quantum confinement structure in which the channel layer 30 in which the 2DEG 1a is generated is sandwiched between the base layer 10 and the barrier layer 20 on the lower layer side and the barrier layer 70 on the upper layer side is realized by forming the barrier layer 70. With the semiconductor device 1B, confinement of electrons serving as carriers is enhanced, and diffusion of electrons in the channel layer 30, the occurrence of a leakage current, a decrease in electron transport efficiency, and the like are suppressed. As a result, the semiconductor device 1B having excellent electron mobility is realized.

In the semiconductor device 1A, the barrier layer is also referred to as a “first barrier layer”. In the semiconductor device 1B, the barrier layer 20 is also referred to as a “first barrier layer” and the barrier layer 70 is also referred to as a “second barrier layer”.

In the semiconductor device 1A and the semiconductor device 1B, the gate electrode 40 may be formed on the channel layer 30 of the semiconductor device 1A and on the barrier layer 70 of the semiconductor device 1B with a gate insulating film (not illustrated) therebetween to have a metal insulator semiconductor (MIS) gate structure. Furthermore, in the semiconductor device 1A and the semiconductor device 1B, the gate electrode 40 may be arranged closer to the source electrode 50 than to the drain electrode 60, that is to say, may be arranged asymmetrically, in order to increase the breakdown voltage.

In addition, the semiconductor device 1A and the semiconductor device 1B each including a HEMT have been taken as an example. However, another semiconductor device, such as a Schottky barrier diode (SBD), may be realized by the use of the semiconductor laminated structure 1 (FIG. 4B and the like) utilizing the N polar plane. For example, a cathode electrode which functions as an ohmic electrode and an anode electrode which functions as a Schottky electrode are formed on the channel layer 30 or on the barrier layer 70 formed on the channel layer 30 to realize an SBD.

### Second Embodiment

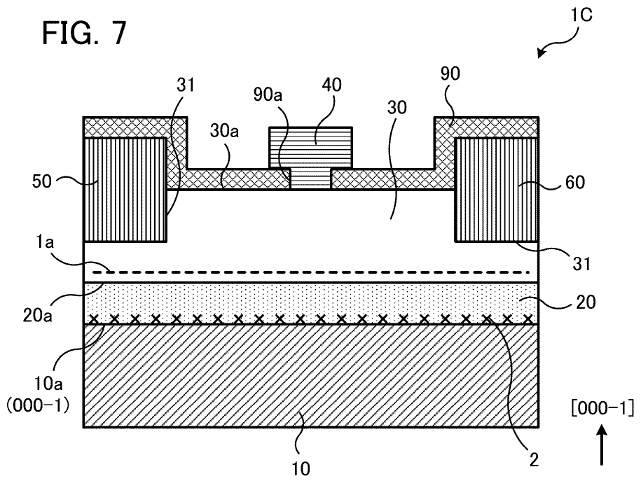

FIG. 7 is a view for describing an example of a semiconductor device according to a second embodiment. FIG. 7 is a fragmentary schematic sectional view of an example of a semiconductor device.

A semiconductor device 1C illustrated in FIG. 7 is an example of a HEMT using a semiconductor laminated structure utilizing an N polar plane. The semiconductor device 1C includes a base layer 10, a barrier layer 20, a channel layer 30, a gate electrode 40, a source electrode 50, a drain electrode 60, and a passivation film 90.

The base layer 10, the barrier layer 20, and the channel layer 30 of the semiconductor device 1C are the same as those described for the semiconductor laminated structure 1 in the first embodiment. The semiconductor device 1C includes the channel layer 30 of GaN formed on the base layer 10 of AlN with the barrier layer 20 of lattice-relaxed AlGaN therebetween. The Al composition of AlGaN of the barrier layer 20 is set to, for example, a value smaller than 0.3. The barrier layer 20 is formed on a surface 10a, which is an N polar plane, of the base layer 10 and the channel layer 30 is formed on a surface 20a, which is an N polar plane, of the barrier layer 20. A 2DEG 1a is generated in the channel layer 30 near the junction interface between the channel layer 30 and the barrier layer 20.

The gate electrode 40 is formed on a surface 30a of the channel layer 30. The source electrode 50 and the drain electrode 60 are formed in a recess 31 formed in the channel layer 30. The source electrode 50 and the drain electrode 60 are formed separately from each other on both sides of the gate electrode 40. For example, a metal, such as Ni or Au, is used for forming the gate electrode 40. For example, a metal, such as Ta or Al, is used for forming the source electrode 50 and the drain electrode 60. The gate electrode 40 is formed so as to function as a Schottky electrode. The source electrode 50 and the drain electrode 60 are formed so as to function as an ohmic electrode.

The passivation film 90 is formed so as to cover the channel layer 30, the source electrode 50, and the drain electrode 60. Various insulating material, such as silicon nitride (SiN), are used for forming the passivation film 90. An opening portion 90a which communicates with the channel layer 30 is formed in the passivation film 90. The gate electrode 40 is formed in the opening portion 90a of the passivation film 90.

The surface 10a of the base layer 10 is also referred to as a “first surface”. The barrier layer 20 formed on the surface 10a side of the base layer 10 is also referred to as a “first barrier layer”. The surface 20a of the barrier layer 20 opposite to the base layer 10 is also referred to as a “second surface”. The surface 30a of the channel layer opposite to the barrier layer 20 is also referred to as a “third surface”.

With the semiconductor device 1C, the same effects that are described for the semiconductor laminated structure 1 in the first embodiment are achievable. That is to say, with the semiconductor device 1C, the barrier layer of lattice-relaxed AlGaN that is not lattice-matched with the base layer 10 of AlN is formed on the base layer 10, and the channel layer 30 of GaN that is lattice-matched with the barrier layer 20 of lattice-relaxed AlGaN is formed on the barrier layer 20. The barrier layer 20 of lattice-relaxed AlGaN is grown on the base layer 10 of AlN. Lattice defects 2 appear at the junction interface between the base layer and the barrier layer 20 or in the barrier layer 20 near the junction interface. On the other hand, the appearance of lattice defects is suppressed at the junction interface between the channel layer 30 of GaN grown on the barrier layer 20 of lattice-relaxed AlGaN and the barrier layer 20 or in the channel layer 30 near the junction interface. Therefore, the disappearance of the 2DEG 1a in the channel layer 30 caused by lattice defects is suppressed and an increase in resistance caused by the disappearance of the 2DEG 1a in the channel layer 30 is suppressed. As a result, the high performance semiconductor device 1C is realized.

Furthermore, with the semiconductor device 1C, the source electrode 50 and the drain electrode 60 are formed in the recess 31 of the channel layer 30. Therefore, the source electrode 50 and the drain electrode 60 approach the 2DEG 1a generated in the channel layer 30, and the connection resistance between the source electrode 50 and the 2DEG 1a in the channel layer 30 and the connection resistance between the drain electrode 60 and the 2DEG 1a in the channel layer are reduced. As a result, the semiconductor device 1C having low on-state resistance is realized.

A method for manufacturing the semiconductor device 1C having the above structure will now be described with reference to FIGS. 8A, 8B, 9A, and 9B and FIG. 7.

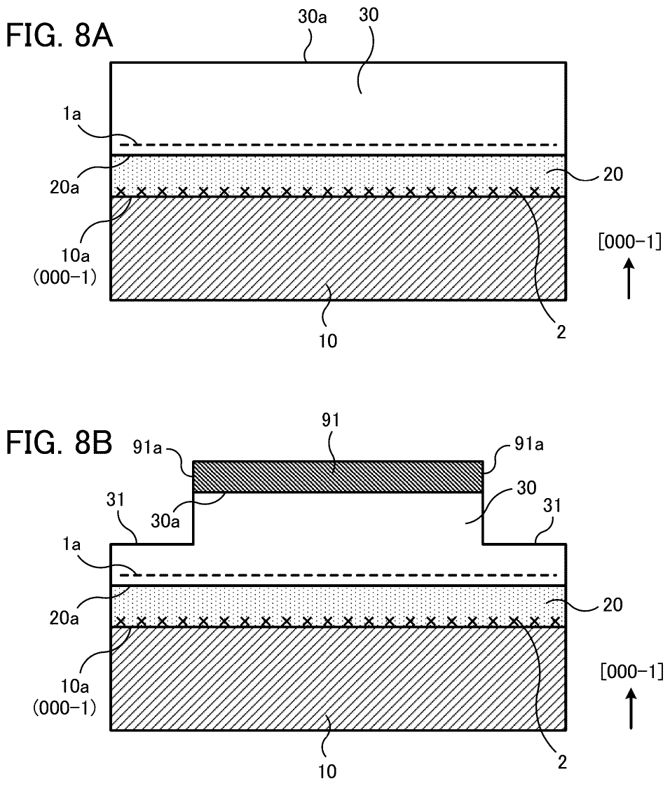

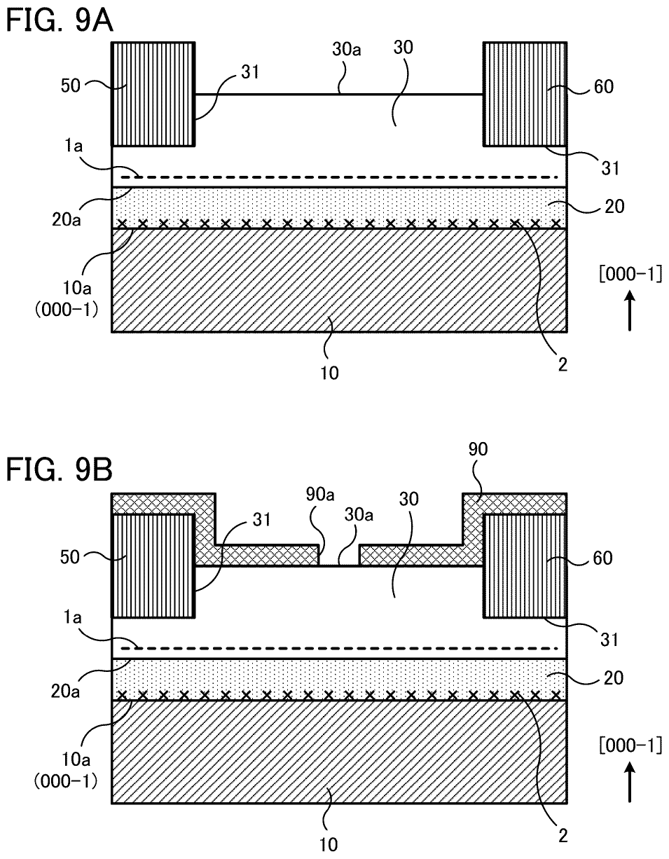

FIGS. 8A, 8B, 9A, and 9B are views for describing an example of a method for manufacturing the semiconductor device according to the second embodiment. Each of FIGS. 8A, 8B, 9A, and 9B is a fragmentary schematic sectional view of an example of a step for manufacturing the semiconductor device.

First, as illustrated in FIG. 8A, the barrier layer 20 and the channel layer 30 are grown in turn on the base layer 10 (in the [000-1] direction) having the surface 10a, which is an N polar plane ((000-1) plane), by the use of, for example, the MOVPE method. For example, an AlN self-supporting substrate is used as the base layer 10. The base layer 10 may be a layer of AlN grown on various substrates such as AlN, GaN, Si, SiC, sapphire, and diamond. For example, AlGaN having an Al composition of less than 0.3 is used as the barrier layer 20. For example, GaN is used as the channel layer 30.

When the MOVPE method is used for growth, first, the barrier layer 20 of AlGaN having a predetermined Al composition is grown on the surface 10a, which is an N polar plane, of the base layer 10. The barrier layer 20 grown on the surface 10a, which is an N polar plane, is grown so as to have the surface 20a which is an N polar plane. The thickness of the barrier layer 20 is set to, for example, 50 nm. There is a relatively large difference in lattice constant between AlN of the base layer 10 and AlGaN of the barrier layer 20 having an Al composition of less than 0.3 have a relatively large lattice constant difference. Therefore, AlGaN of the barrier layer 20 is not lattice-matched with AlN of the base layer 10. As a result, AlGaN of the barrier layer 20 grows while introducing dislocations, and lattice relaxation occurs. Lattice defects 2 appear at the junction interface between the barrier layer 20 of lattice-relaxed AlGaN and the base layer 10 of AlN or in the barrier layer 20 near the junction interface.

The channel layer 30 of GaN is grown on the surface 20a, which is an N polar plane, of the grown barrier layer 20. The channel layer 30 grown on the surface 20a, which is an N polar plane, is grown so as to have the surface 30a, which is an N polar plane. The thickness of the channel layer 30 is set to, for example, 50 nm. The difference in lattice constant between GaN of the channel layer 30 and AlGaN of the barrier layer 20 grown on AlN of the base layer 10 in a lattice-relaxed state is relatively little. Therefore, GaN of the channel layer 30 is lattice-matched with AlGaN of the barrier layer 20. As a result, GaN of the channel layer 30 grows on the surface 20a while suppressing introduction of dislocations. This suppresses the appearance of lattice defects at the junction interface between the channel layer 30 of GaN and the barrier layer 20 of AlGaN or in the channel layer 30 near the junction interface.

The 2DEG 1a is generated in the channel layer 30 near the junction interface between the barrier layer 20 and the channel layer 30 by polarization of the base layer 10 and the barrier layer 20. Because the appearance of lattice defects at the junction interface between the channel layer and the barrier layer 20 or in the channel layer 30 near the junction interface is suppressed, the disappearance of the 2DEG 1a in the channel layer 30 is effectively suppressed. The thickness of AlN of the base layer 10 in the [000-1] direction is preferably 200 nm or more from the viewpoint of generating spontaneous polarization and piezoelectric polarization for generating a sufficient 2DEG 1a in the channel layer 30.

When each layer is grown by the use of the MOVPE method, tri-methyl-aluminum is used as an Al source, tri-methyl-gallium (TMGa) is used as a Ga source, and ammonia (NH₃) is used as an N source. The supply and stop (switching) of TMGa or TMAl and a flow rate at supply time (mixing ratio with other raw materials) are properly set according to a nitride semiconductor to be grown. Hydrogen (H₂) or nitrogen (N₂) is used as carrier gas. A pressure condition at growth time is in the range of about 1 to 100 kPa. A temperature condition at growth time is in the range of about 600° C. to 1500° C.

After the semiconductor laminated structure of the base layer 10, the barrier layer 20, and the channel layer 30 is formed, an element isolation region (not illustrated) is formed. For example, first, a mask (not illustrated) having an opening portion in a region where the element isolation region is to be formed is formed by photolithography. Then, dry etching using chlorine-based gas or implantation of ions, such as argon (Ar) is performed on the semiconductor laminated structure in the opening portion of the mask to form the element isolation region. After the element isolation region is formed, the mask is removed.

After the above semiconductor laminated structure and element isolation region are formed, as illustrated in FIG. 8B, a surface protection film 91 having an opening portion 91a in a region where the recess 31 is to be formed is formed on the surface 30a of the channel layer 30. For example, various insulating materials such as an oxide, a nitride, and an oxynitride containing at least one of Si, Al, hafnium (Hf), zirconium (Zr), titanium (Ti), Ta, and tungsten (W) are used for forming the surface protection film 91. For example, silicon oxide (SiO₂), SiN, or the like is used for forming the surface protection film 91. For example, a plasma chemical vapor deposition (CVD) method is used for forming the surface protection film 91. In addition, the surface protection film 91 may be formed by the use of an atomic layer deposition (ALD) method, a sputtering method, or the like. The surface protection film 91 having the opening portion 91a is obtained by, for example, forming a material for the surface protection film 91 on the entire surface by the use of the plasma CVD method or the like, and then forming the opening portion 91a in a predetermined region by the photolithography and dry etching using chlorine-based or fluorine-based gas.

After the surface protection film 91 having the opening portion 91a is formed, dry etching using chlorine-based gas is performed on the channel layer 30 in the opening portion 91a. By doing so, as illustrated in FIG. 8B, a part of the channel layer 30 in the opening portion 91a of the surface protection film 91 is removed and the recess 31 is formed in the channel layer 30. After the recess 31 is formed, the surface protection film 91 is removed.

After the recess 31 is formed, as illustrated in FIG. 9A, the source electrode 50 and the drain electrode 60 are formed in the recess 31 formed in the channel layer 30. At this time, first, an electrode metal is formed in the recess 31 by the use of the photolithography, a vapor deposition technique, and a lift-off technique. For example, a laminate of Ta having a thickness of 20 nm and Al having a thickness of 200 nm is formed as the electrode metal. Then, after the electrode metal is formed, heat treatment is performed in a nitrogen atmosphere under a temperature condition in the range of 400° C. to 1000° C., for example, at a temperature of 550° C. and an ohmic contact of the electrode metal is established. As a result, the source electrode 50 and the drain electrode 60 are formed in the recess 31 of the channel layer 30.

After the source electrode 50 and the drain electrode 60 are formed, as illustrated in FIG. 9B, the passivation film 90 is formed so as to cover the channel layer 30, the source electrode 50, and the drain electrode 60. For example, various insulating materials, such as an oxide, a nitride, and an oxynitride containing at least one of Si, Al, Hf, Zr, Ti, Ta, and W are used for forming the passivation film 90. For example, SiN or the like is used for forming the passivation film 90. For example, the passivation film 90 of SiN or the like having a thickness in the range of 2 to 500 nm, for example, a thickness of 100 nm is formed by the use of the plasma CVD method. The passivation film 90 may be formed by the use of the ALD method, the sputtering method, or the like.

After the passivation film 90 is formed, as illustrated in FIG. 9B, the passivation film 90 in a region where the gate electrode 40 is to be formed is partially removed, and an opening portion 90a which communicates with the channel layer 30 is formed. In this case, first, a mask (not illustrated) having an opening portion in a region where the gate electrode 40 is to be formed is formed by the photolithography and dry etching is performed. By this etching, the passivation film 90 exposed from the opening portion of the mask is removed and the opening portion 90a of the passivation film 90 is formed. The etching of the passivation film 90 is performed by, for example, dry etching using fluorine-based or chlorine-based gas. In addition, the etching of the passivation film 90 may be performed by wet etching using hydrofluoric acid, buffered hydrofluoric acid, or the like. After the opening portion 90a is formed by etching the passivation film 90, the mask is removed.

After the opening portion 90a of the passivation film 90 is formed, the gate electrode 40 is formed at the position of the opening portion 90a as illustrated in FIG. 7. At this time, an electrode metal is formed at the position of the opening portion 90a of the passivation film 90 by the use of the photolithography, the vapor deposition technique, and the lift-off technique. For example, a laminate of Ni having a thickness of 30 nm and Au having a thickness of 400 nm is formed as the electrode metal. The electrode metal is formed so as to cover the upper surface of the passivation film 90 and enter the opening portion 90a. By doing so, the gate electrode 40 which functions as a Schottky electrode is formed.

The semiconductor device 1C illustrated in FIG. 7 is manufactured by the above steps.

With the semiconductor device 1C, the type of metals and layer structures used for the gate electrode 40, the source electrode 50, and the drain electrode 60 are not limited to the above example, and methods for forming them are not limited to the above example. Each of the gate electrode 40, the source electrode 50, and the drain electrode 60 may have a single-layer structure or a laminated structure. When the source electrode 50 and the drain electrode 60 are formed, the above heat treatment is not always needed as long as ohmic contact is realized by forming the electrode metals. When the gate electrode 40 is formed, heat treatment may be further performed after the formation of the electrode metal.

An example in which the semiconductor device 1C includes the gate electrode 40 that functions as a Schottky electrode has been taken. However, a gate insulating film using an oxide, a nitride, an oxynitride, or the like may be formed between the gate electrode 40 and the channel layer 30 to form an MIS type gate structure. Furthermore, in order to increase breakdown voltage, the gate electrode may be asymmetrically arranged closer to the source electrode 50 than to the drain electrode 60.

### Third Embodiment

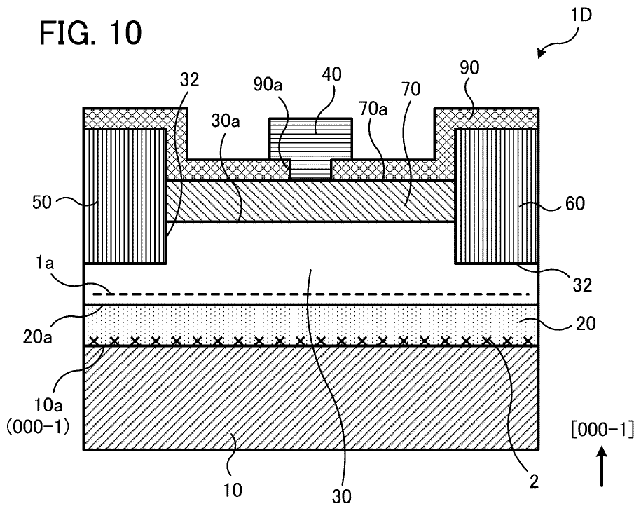

FIG. 10 is a view for describing an example of a semiconductor device according to a third embodiment. FIG. is a fragmentary schematic sectional view of an example of a semiconductor device.

A semiconductor device 1D illustrated in FIG. 10 is an example of a HEMT using a semiconductor laminated structure utilizing an N polar plane. The semiconductor device 1D includes a barrier layer 70 formed on a surface 30a, which is an N polar plane, of a channel layer 30. A nitride semiconductor, such as InAlGaN, AlGaN, InAlN, or AlN, having a band gap larger than that of GaN of the channel layer 30 is used for forming the barrier layer 70. With the semiconductor device 1D, a gate electrode 40 is formed on a surface 70a of the barrier layer 70 and a source electrode 50 and a drain electrode 60 are formed in a recess 32 which pierces the barrier layer 70 and which reaches the channel layer 30. The semiconductor device 1D differs from the semiconductor device 1C (FIG. 7) described in the above second embodiment in that the semiconductor device 1D has the above structure.

A surface 10a of a base layer 10 is also referred to as a “first surface”. A barrier layer 20 formed on a surface 10a of the base layer 10 is also referred to as a “first barrier layer”. A surface 20a of the barrier layer opposite to the base layer 10 is also referred to as a “second surface”. A surface 30a of the channel layer 30 opposite to the barrier layer 20 is also referred to as a “third surface”. The barrier layer 70 formed on the surface 30a of the channel layer 30 is also referred to as a “second barrier layer”.

With the semiconductor device 1D, the same effects that are obtained by the above semiconductor device 1C are obtained. That is to say, the barrier layer 20 of lattice-relaxed AlGaN that is not lattice-matched with the base layer 10 of AlN is formed on the base layer 10 and the channel layer 30 of GaN that is lattice-matched with the barrier layer 20 of lattice-relaxed AlGaN is formed on the barrier layer 20. The appearance of lattice defects is suppressed at the junction interface between the channel layer 30 of GaN and the barrier layer 20 of AlGaN or in the channel layer 30 near the junction interface. Therefore, the disappearance of a 2DEG 1a in the channel layer 30 caused by lattice defects is suppressed and an increase in resistance caused by the disappearance of the 2DEG 1a in the channel layer 30 is suppressed. As a result, the high performance semiconductor device 1D is realized.

In addition, because the source electrode 50 and the drain electrode 60 are formed in the barrier layer 70 and the recess 32 of the channel layer 30, the connection resistance between the source electrode 50 and the 2DEG 1a in the channel layer 30 and the connection resistance between the drain electrode 60 and the 2DEG 1a in the channel layer are reduced. As a result, the semiconductor device 1D having low on-state resistance is realized.

Furthermore, with the semiconductor device 1D, a quantum confinement structure is realized in which the channel layer 30 in which the 2DEG 1a is generated is sandwiched between the base layer 10 and the barrier layer on the lower layer side and the barrier layer 70 on the upper layer side. Therefore, confinement of electrons serving as carriers is enhanced and diffusion of electrons in the channel layer 30, the occurrence of a leakage current, a decrease in electron transport efficiency, and the like are suppressed. As a result, the semiconductor device 1D having excellent electron mobility is realized.

A method for manufacturing the semiconductor device 1D having the above structure will now be described with reference to FIGS. 11A, 11B, 12A, and 12B and FIG. 10.

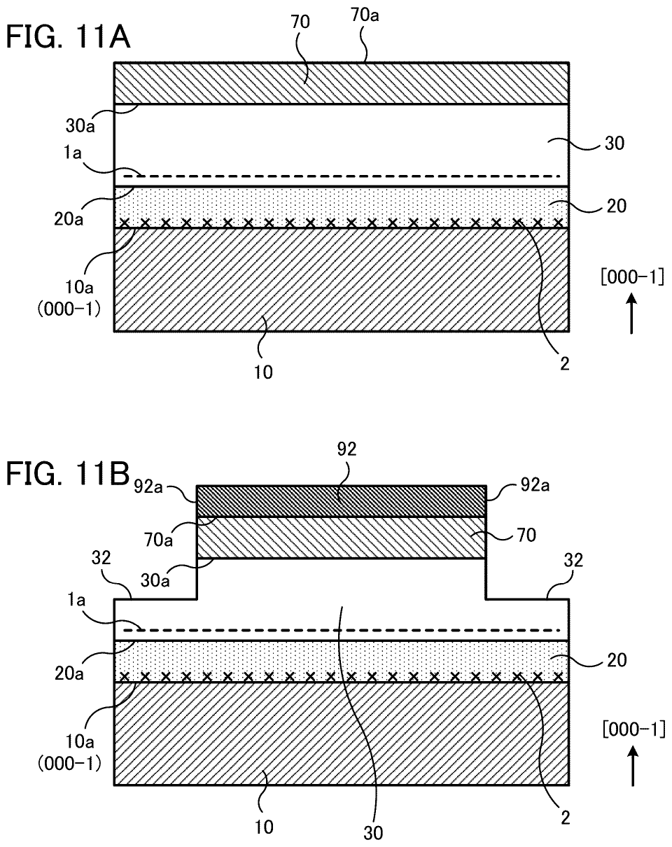

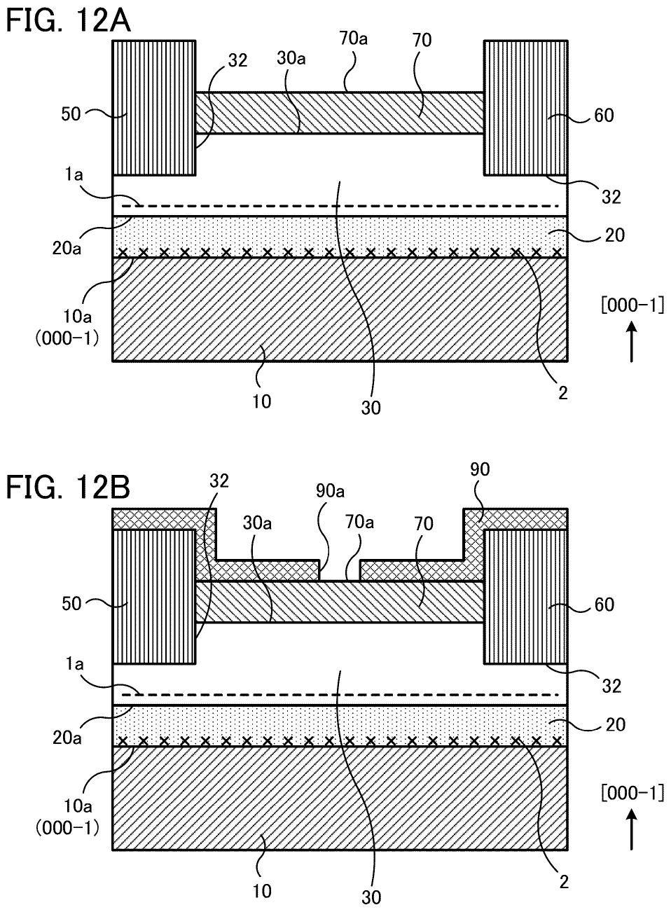

FIGS. 11A, 11B, 12A, and 12B are views for describing an example of a method for manufacturing the semiconductor device according to the third embodiment. Each of FIGS. 11A, 11B, 12A, and 12B is a fragmentary schematic sectional view of an example of a step for manufacturing the semiconductor device.

In order to manufacture the semiconductor device 1D, the barrier layer 20 and the channel layer 30 are grown in turn on the base layer 10 by the use of, for example, the MOVPE method in accordance with the example of the step of FIG. 8A described for manufacturing the above semiconductor device 1C. After that, as illustrated in FIG. 11A, the barrier layer 70 is further grown. A nitride semiconductor, such as InAlGaN, AlGaN, InAlN, or AlN, having a band gap larger than that of GaN of the channel layer 30, that is to say, a nitride semiconductor expressed by the general formula In_{y}Al_{z}Ga_{1-y-z}N (0≤y≤0.2 and 0<z≤1) is used for forming the barrier layer 70. The barrier layer 70 is grown on the surface 30a, which is an N polar plane, of the channel layer 30 by the use of such a nitride semiconductor. The thickness of the barrier layer 20 is set to, for example, nm.

When each layer is grown by the use of the MOVPE method, TMAL is used as an Al source, TMGa is used as a Ga source, and tri-methyl-indium (TMIn) is used as an In source, and NH₃ is used as an N source. The supply and stop (switching) of TMGa, TMAl, or TMIn, and a flow rate at supply time (mixing ratio with other raw materials) are properly set according to nitride semiconductors to be grown. H₂ or N₂ is used as carrier gas. A pressure condition at growth time is in the range of about 1 to 100 kPa. A temperature condition at growth time is in the range of about 600° C. to 1500° C.

After a semiconductor laminated structure of the base layer 10, the barrier layer 20, the channel layer 30, and the barrier layer 70 is formed, an element isolation region (not illustrated) is formed in accordance with the example described in the above second embodiment. After the semiconductor laminated structure and the element isolation region are formed, as illustrated in FIG. 11B, a surface protection film 92 having an opening portion 92a in a region where the recess 32 is to be formed is formed on the surface 70a of the barrier layer 70 in accordance with the example of FIG. 8B described in the above second embodiment. Furthermore, a part of the barrier layer 70 and a part of the channel layer 30 in the opening portion 92a of the surface protection film 92 are removed by dry etching using chlorine-based gas and the recess 32 is formed. After the recess 32 is formed, the surface protection film 92 removed.

After the recess 32 is formed, as illustrated in FIG. 12A, the source electrode 50 and the drain electrode 60 are formed in the recess 32 in accordance with the example of FIG. 9A. After that, as illustrated in FIG. 12B, a passivation film 90 is formed in accordance with the example of FIG. 9B so as to cover the barrier layer 70, the source electrode 50, and the drain electrode 60, and an opening portion 90a which communicates with the barrier layer 70 is formed in a region where the gate electrode 40 is to be formed. In addition, as illustrated in FIG. 10, the gate electrode 40 is formed at the position of the opening portion 90a of the passivation film 90 in accordance with the example described in the above second embodiment.

The semiconductor device 1D illustrated in FIG. is manufactured by the above steps.

With the semiconductor device 1D, the type of metals and layer structures used for the gate electrode 40, the source electrode 50, and the drain electrode 60 are not limited to the above example, and methods for forming them are not limited to the above example. When the source electrode 50 and the drain electrode 60 are formed, the above heat treatment is not always needed as long as ohmic contact is realized by forming the electrode metals. When the gate electrode 40 is formed, heat treatment may be further performed after the formation of the electrode metal.

An example in which the semiconductor device 1D includes the gate electrode 40 which functions as a Schottky electrode has been taken. However, the gate electrode 40 may have a MIS type gate structure. Furthermore, the gate electrode 40 may be asymmetrically arranged closer to the source electrode 50 than to the drain electrode 60.

### Fourth Embodiment

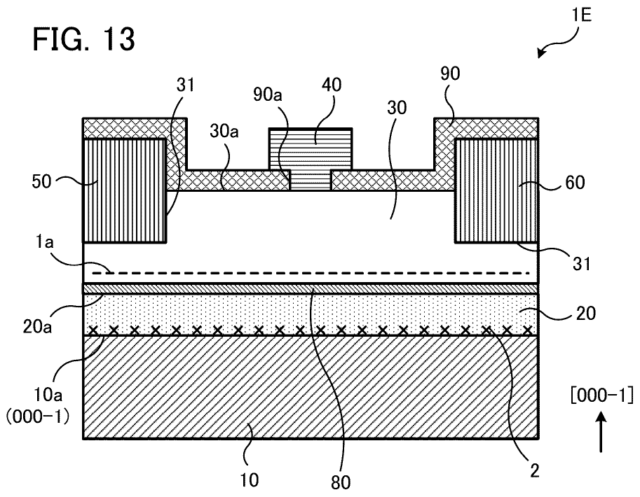

FIG. 13 is a view for describing an example of a semiconductor device according to a fourth embodiment. FIG. 13 is a fragmentary schematic sectional view of an example of a semiconductor device.

A semiconductor device 1E illustrated in FIG. 13 is an example of a HEMT using a semiconductor laminated structure utilizing an N polar plane. The semiconductor device 1E includes a spacer layer 80 formed between a barrier layer 20 and a channel layer 30. The semiconductor device 1E differs from the semiconductor device 1C (FIG. 7) described in the above second embodiment in that the semiconductor device 1E has such a structure.

A nitride semiconductor, such as AlGaN or AlN, having a band gap larger than that of GaN of the channel layer 30 is used for forming the spacer layer 80. The thickness of the spacer layer 80 is set to, for example, 2 nm. The spacer layer 80 is preferably made of a nitride semiconductor that is lattice-matched with the barrier layer and the channel layer 30, for example, a nitride semiconductor having an Al composition that is lattice-matched with the barrier layer 20 and the channel layer 30.

In order to manufacture the semiconductor device 1E, the barrier layer 20 is grown on the base layer 10. After that, the spacer layer 80 is grown and the channel layer 30 is grown thereon. The MOVPE method is used for the growth of the spacer layer 80. This is the same with the other layers. The other steps for manufacturing the semiconductor device 1E are performed in the same way as in the manufacture of the semiconductor device 1C described in the above second embodiment.

The same effects that are obtained in the above semiconductor device 1C are obtained in the semiconductor device 1E. That is to say, because the channel layer 30 of GaN is formed on the base layer 10 of AlN with the barrier layer 20 of lattice-relaxed AlGaN and the spacer layer 80 formed thereon therebetween, the appearance of lattice defects in the channel layer 30 of GaN is suppressed. As a result, the high-performance semiconductor device 1E in which the disappearance of a 2DEG 1a in channel layer 30 is suppressed and in which an increase in resistance caused by the disappearance of the 2DEG 1a is suppressed is realized.

In addition, because the source electrode 50 and the drain electrode 60 are formed in a recess 31 of the channel layer 30, the connection resistance between the source electrode 50 and the 2DEG 1a in the channel layer 30 and the connection resistance between the drain electrode 60 and the 2DEG 1a in the channel layer 30 are reduced and the semiconductor device 1E having low on-state resistance is realized.

Furthermore, with the semiconductor device 1E, because the spacer layer 80 is formed between the barrier layer 20 and the channel layer 30, the influence of alloy scattering from the barrier layer 20 is suppressed and the resistance of the channel layer 30 is reduced. Accordingly, the semiconductor device 1E having low on-state resistance is realized.

With the semiconductor device 1E, a barrier layer 70 may be formed on the channel layer 30 in accordance with the example of the semiconductor device 1D (FIG. 10) described in the above third embodiment. A quantum confinement structure in which the channel layer 30 in which the 2DEG 1a is generated is sandwiched between the base layer 10, the barrier layer 20, and the spacer layer 80 on the lower layer side and the barrier layer 70 on the upper layer side may be realized in this way.

The first to fourth embodiments have been described.

The above semiconductor devices 1A, 1B, 1C, 1D, 1E (also referred to as “1A-1E”) and the like may be applied to various electronic devices. For example, a case where the semiconductor devices having the above structures are applied to a semiconductor package, a power factor correction circuit, a power supply device, and an amplifier will now be described.

### Fifth Embodiment

An example in which the semiconductor devices having the above structures are applied to a semiconductor package will now be described as a fifth embodiment.

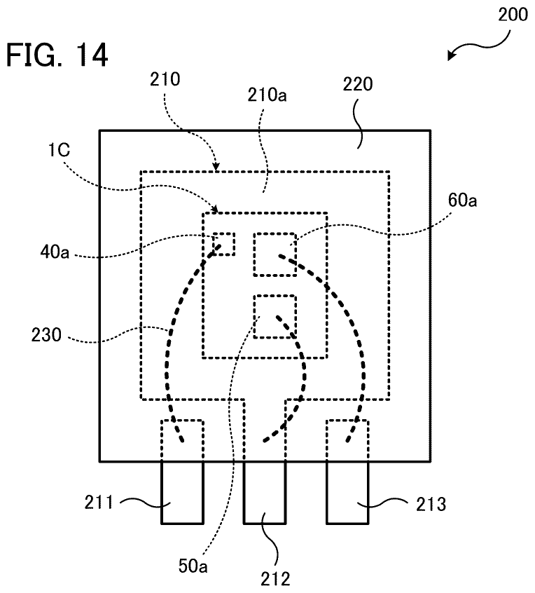

FIG. 14 is a view for describing an example of a semiconductor package according to a fifth embodiment. FIG. 14 is a fragmentary schematic plan view of an example of a semiconductor package.

A semiconductor package 200 illustrated in FIG. 14 is an example of a discrete package. The semiconductor package 200 includes, for example, the semiconductor device 1C (FIG. 7 and the like) described in the above second embodiment, a lead frame 210 on which the semiconductor device 1C is mounted, and resin 220 that seals them.

The semiconductor device 1C is mounted on, for example, a die pad 210a of the lead frame 210 by the use of a die attach material or the like (not illustrated). The semiconductor device 1C includes a pad 40a connected to the gate electrode 40, a pad 50a connected to the source electrode 50, and a pad 60a connected to the drain electrode 60. The pad 40a, the pad 50a, and the pad 60a are connected to a gate lead 211, a source lead 212, and a drain lead 213, respectively, of the lead frame 210 by the use of wires 230 made of Au, Al, or the like. The lead frame 210, the semiconductor device 1C mounted thereon, and the wires 230 connecting them are sealed with the resin 220 so that the gate lead 211, the source lead 212, and the drain lead 213 are partially exposed.

An external connection electrode connected to the source electrode 50 may be formed on the surface of the semiconductor device 1C opposite to the surface on which the pad 40a connected to the gate electrode 40 and the pad 60a connected to the drain electrode 60 are formed. The external connection electrode may be connected to the die pad 210a connected to the source lead 212 by the use of a conductive bonding material such as solder.

For example, the semiconductor device 1c described in the above second embodiment is used and the semiconductor package 200 having the above structure is obtained.

As described above, the semiconductor device 1C is an example of a HEMT utilizing an N polar plane. With the semiconductor device 1C, the channel layer 30 of GaN is formed on the base layer 10 of AlN with the barrier layer of lattice-relaxed AlGaN therebetween. The lattice defects 2 appear at the junction interface between the barrier layer 20 of lattice-relaxed AlGaN grown on the base layer 10 of AlN and the base layer 10 or in the barrier layer 20 near the junction interface. On the other hand, the appearance of lattice defects is suppressed at the junction interface between the channel layer 30 of GaN grown on the barrier layer 20 of lattice-relaxed AlGaN and the barrier layer 20 or in the channel layer 30 near the junction interface. As a result, the disappearance of the 2DEG 1a in the channel layer 30 is suppressed. Therefore, the high-performance semiconductor device 1C in which the increase in resistance caused by the disappearance of the 2DEG 1a is suppressed is realized. This semiconductor device 1C is used and the high performance semiconductor package 200 is realized.

The semiconductor device 1C has been taken as an example. However, a semiconductor package is obtained in the same way by the use of the other semiconductor devices 1A, 1B, 1D, 1E, and the like.

### Sixth Embodiment

An example in which the semiconductor devices having the above structures are applied to a power factor correction circuit will now be described as a sixth embodiment.

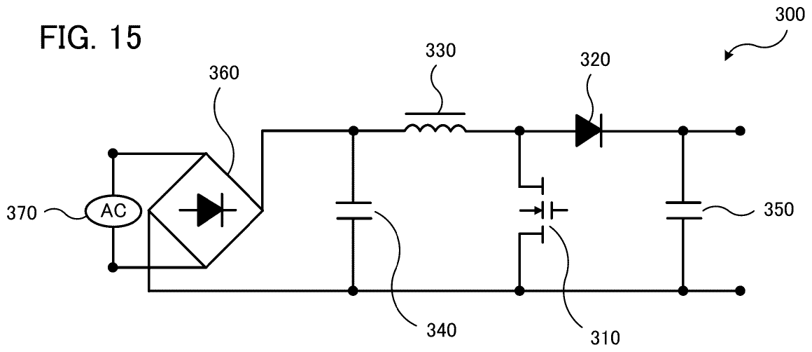

FIG. 15 is a view for describing an example of a power factor correction circuit according to a sixth embodiment. FIG. 15 illustrates an equivalent circuit diagram of an example of a power factor correction circuit.

A power factor correction (PFC) circuit 300 illustrated in FIG. 15 includes a switching element 310, a diode 320, a choke coil 330, a capacitor 340, a capacitor 350, a diode bridge 360, and an alternating current (AC) power supply 370.

In the PFC circuit 300, a drain electrode of the switching element 310 is connected to an anode terminal of the diode 320 and one terminal of the choke coil 330. A source electrode of the switching element 310 is connected to one terminal of the capacitor 340 and one terminal of the capacitor 350. The other terminal of the capacitor 340 and the other terminal of the choke coil 330 are connected to each other. The other terminal of the capacitor 350 and a cathode terminal of the diode 320 are connected to each other. Furthermore, a gate driver is connected to a gate electrode of the switching element 310. The AC power supply 370 is connected between both terminals of the capacitor 340 via the diode bridge 360, and a direct-current (DC) voltage is taken out from between both terminals of the capacitor 350.

For example, the above semiconductor devices 1A to 1E and the like are used for the switching element 310 of the PFC circuit 300 having the above structure.

As described above, each of the semiconductor devices 1A to 1E and the like is an example of a HEMT utilizing an N polar plane. With the semiconductor devices 1A to 1E and the like, the channel layer 30 of GaN is formed on the base layer 10 of AlN with the barrier layer 20 of lattice-relaxed AlGaN therebetween. Lattice defects 2 appear at the junction interface between the barrier layer 20 of lattice-relaxed AlGaN grown on the base layer 10 of AlN and the base layer 10 or in the barrier layer 20 near the junction interface. On the other hand, the appearance of lattice defects is suppressed at the junction interface between the channel layer 30 of GaN grown on the barrier layer 20 of lattice-relaxed AlGaN and the barrier layer 20 or in the channel layer 30 near the junction interface. As a result, the disappearance of the 2DEG 1a in the channel layer 30 is suppressed. Therefore, the high performance semiconductor devices 1A to 1E and the like in which an increase in resistance caused by the disappearance of the 2DEG 1a is suppressed are realized. These semiconductor devices 1A to 1E and the like are used and the high performance PFC circuit 300 is realized.

### Seventh Embodiment

An example in which the semiconductor devices having the above structures are applied to a power supply device will now be described as a seventh embodiment.

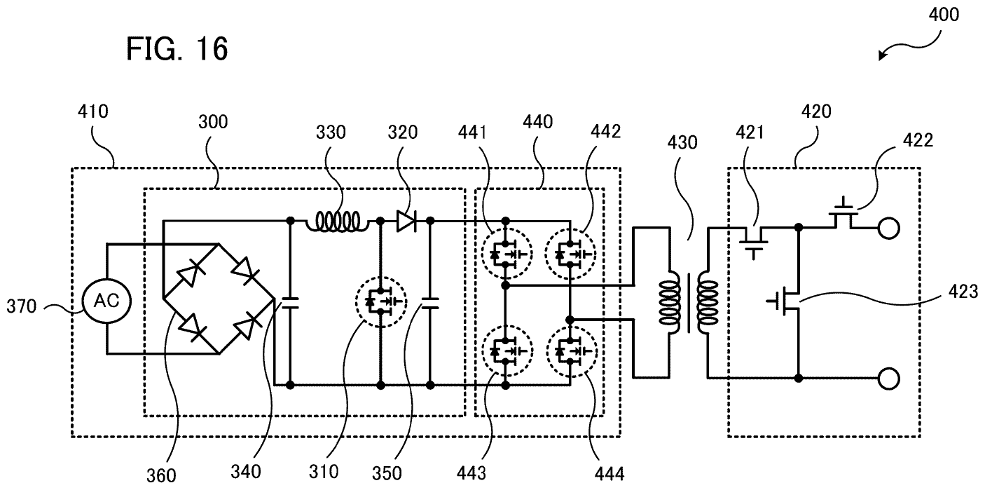

FIG. 16 is a view for describing an example of a power supply device according to a seventh embodiment. FIG. 16 illustrates an equivalent circuit diagram of an example of a power supply device.

A power supply device 400 illustrated in FIG. 16 includes a primary-side circuit 410, a secondary-side circuit 420, and a transformer 430 located between the primary-side circuit 410 and the secondary-side circuit 420.

The primary-side circuit 410 includes the PFC circuit 300 described in the above fifth embodiment, and an inverter circuit connected between both terminals of the capacitor 350 of the PFC circuit 300, for example, a full-bridge inverter circuit 440. The full-bridge inverter circuit 440 includes a plurality of, for example, four switching elements 441, 442, 443, and 444.

The secondary-side circuit 420 includes a plurality of, for example, three switching elements 421, 422, and 423.

For example, the semiconductor devices 1A to 1E and the like are used for the switching element 310 of the PFC circuit 300 and the switching elements 441 to 444 of the full-bridge inverter circuit 440 included in the primary-side circuit 410 of the power supply device 400 having the above structure. For example, normal MIS field-effect transistors using Si are used as the switching elements 421, 422, and 423 of the secondary-side circuit 420 of the power supply device 400.

As described above, each of the semiconductor devices 1A to 1E and the like is an example of a HEMT utilizing an N polar plane. With the semiconductor devices 1A to 1E and the like, the channel layer 30 of GaN is formed on the base layer 10 of AlN with the barrier layer 20 of lattice-relaxed AlGaN therebetween. Lattice defects 2 appear at the junction interface between the barrier layer 20 of lattice-relaxed AlGaN grown on the base layer 10 of AN and the base layer 10 or in the barrier layer 20 near the junction interface. On the other hand, the appearance of lattice defects is suppressed at the junction interface between the channel layer 30 of GaN grown on the barrier layer 20 of lattice-relaxed AlGaN and the barrier layer 20 or in the channel layer 30 near the junction interface. As a result, the disappearance of the 2DEG 1a in the channel layer 30 is suppressed. Therefore, the high performance semiconductor devices 1A to 1E and the like in which an increase in resistance caused by the disappearance of the 2DEG 1a is suppressed are realized. These semiconductor devices 1A to 1E and the like are used and the high performance power supply device 400 is realized.

### Eighth Embodiment

An example in which the semiconductor devices having the above structures are applied to an amplifier will now be described as an eighth embodiment.

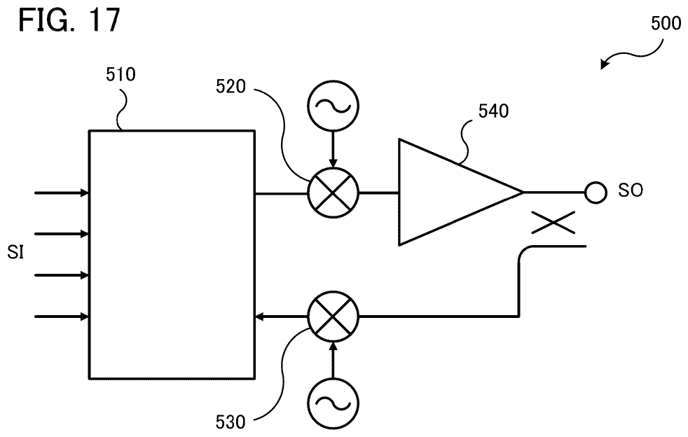

FIG. 17 is a view for describing an example of an amplifier according to an eighth embodiment. FIG. 17 illustrates an equivalent circuit diagram of an example of an amplifier.

An amplifier 500 illustrated in FIG. 17 includes a digital predistortion circuit 510, a mixer 520, a mixer 530, and a power amplifier 540.

The digital predistortion circuit 510 compensates for nonlinear distortion of an input signal. The mixer 520 mixes an input signal SI whose nonlinear distortion has been compensated for with an AC signal. The power amplifier 540 amplifies a signal obtained by mixing the input signal SI with the AC signal. With the amplifier 500, for example, an output signal SO may be mixed with an AC signal by the mixer 530 by switching a switch and a signal obtained may be sent to the digital predistortion circuit 510. The amplifier 500 is used as a high-frequency amplifier or a high output amplifier.

The above semiconductor devices 1A to 1E and the like are used for the power amplifier 540 of the amplifier 500 having the above structure.

As described above, each of the semiconductor devices 1A to 1E and the like is an example of a HEMT utilizing an N polar plane. With the semiconductor devices 1A to 1E and the like, the channel layer 30 of GaN is formed on the base layer 10 of AlN with the barrier layer 20 of lattice-relaxed AlGaN therebetween. Lattice defects 2 appear at the junction interface between the barrier layer 20 of lattice-relaxed AlGaN grown on the base layer 10 of AlN and the base layer 10 or in the barrier layer 20 near the junction interface. On the other hand, the appearance of lattice defects is suppressed at the junction interface between the channel layer 30 of GaN grown on the barrier layer 20 of lattice-relaxed AlGaN and the barrier layer 20 or in the channel layer 30 near the junction interface. As a result, the disappearance of the 2DEG 1a in the channel layer 30 is suppressed. Therefore, the high performance semiconductor devices 1A to 1E and the like in which an increase in resistance caused by the disappearance of the 2DEG 1a is suppressed are realized. These semiconductor devices 1A to 1E and the like are used and the high performance amplifier 500 is realized.

Various electronic devices (semiconductor package 200, the PFC circuit 300, the power supply device 400, the amplifier 500, and the like described in the above fifth to eighth embodiments respectively) to which the semiconductor devices 1A to 1E and the like are applied may be mounted on various electronic apparatuses or electronic devices. For example, they may be mounted on various electronic apparatuses or electronic devices such as a computer (a personal computer, a supercomputer, a server, or the like), a smartphone, a mobile phone, a tablet terminal, a sensor, a camera, an audio device, a measurement device, an inspection device, a manufacturing device, a transmitter, a receiver, and a radar device.

In one aspect, it is possible to realize a high performance semiconductor device in which an increase in resistance caused by the disappearance of a 2DEG is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a base layer having a first surface and containing AlN, the first surface being a (000-1) plane;
a first barrier layer provided on a first surface side of the base layer where the first surface is provided, the first barrier layer containing AlGaN and being lattice-relaxed with respect to the base layer; and
a channel layer provided on a second surface side of the first barrier layer opposite to the base layer, the channel layer containing GaN.

2. The semiconductor device according to claim 1, wherein an Al composition of the AlGaN contained in the first barrier layer is less than 0.3.

3. The semiconductor device according to claim 1, wherein the first barrier layer is lattice-mismatched with the base layer, and the channel layer is lattice-matched with the first barrier layer.

4. The semiconductor device according to claim 1, further comprising a second barrier layer provided on a third surface side of the channel layer opposite to the first barrier layer, the second barrier layer containing a nitride semiconductor.

5. The semiconductor device according to claim 1, further comprising a spacer layer provided between the first barrier layer and the channel layer and containing a nitride semiconductor.

6. The semiconductor device according to claim 1, wherein a dislocation density of the channel layer is higher than a dislocation density of the base layer.

7. The semiconductor device according to claim 1, wherein the base layer has a thickness of 200 nm or more in a [000-1] direction.

8. The semiconductor device according to claim further comprising:
a gate electrode provided on a third surface side of the channel layer opposite to the first barrier layer; and
a source electrode and a drain electrode provided on both sides of the gate electrode on the third surface side of the channel layer.

9. The semiconductor device according to claim 1, wherein the base layer is an AlN self-supporting substrate.

10. A method for manufacturing a semiconductor device, the method comprising:
forming a first barrier layer on a first surface side of a base layer, the first barrier layer containing AlGaN and being lattice-relaxed with respect to the base layer, the base layer having a first surface on the first surface side and containing AlN, the first surface being a (000-1) plane; and
forming a channel layer containing GaN on a second surface side of the first barrier layer opposite to the base layer.

11. An electronic device comprising a semiconductor device including:
a base layer having a first surface and containing AlN, the first surface being a (000-1) plane;
a first barrier layer provided on a first surface side of the base layer where the first surface is provided, the first barrier layer containing AlGaN and being lattice-relaxed with respect to the base layer; and
a channel layer provided on a second surface side of the first barrier layer opposite to the base layer, the channel layer containing GaN.
